(19) United States
(12) Patent Application Publication
(10) Pub. No.: US 2014/0083479 A1
(43) Pub. Date: Mar. 27, 2014

(54) PHOTOVOLTAIC CELL MODULE

(71) Applicant: KABUSHIKI KAISHA TOSHIBA, Tokyo (JP)

(72) Inventors: Satoshi Takayama, Kanagawa-ken (JP); Haruhi Oooka, Kanagawa-ken (JP); Hideyuki Nakao, Tokyo (JP); Yuki Kudo, Kanagawa-ken (JP); Akihiko Ono, Tokyo (JP); Michihiko Inaba, Kanagawa-ken (JP)

(73) Assignee: KABUSHIKI KAISHA TOSHIBA, Tokyo (JP)

(21) Appl. No.: 14/022,452

(22) Filed: Sep. 10, 2013

(30) Foreign Application Priority Data
Sep. 26, 2012 (JP) 2012-213150

(51) Int. Cl. H01L 31/052

(52) U.S. Cl. CPC H01L 31/0527
USPC 136/246

(57) ABSTRACT

In accordance with one embodiment, there is provided a photovoltaic cell module including a substrate; a plurality of photovoltaic cells disposed via an individual gap on the substrate; and a transparent member disposed to cover the photovoltaic cells, and configured so that light incident on the transparent member passes through the transparent member and arrives at the photovoltaic cells, wherein the transparent member has a slit-shaped recess space at a position corresponding to the individual gap between the photovoltaic cells; and the photovoltaic cell module includes a photoelectric conversion rate improvement structure on a surface side of the transparent member, on which light is incident.

### CROSS REFERENCE TO RELATED APPLICATIONS

This application is based upon and claims the benefit of priority from the prior Japanese Patent Application No. 2012-213150, filed on Sep. 26, 2012, the entire contents of which are incorporated herein by reference.

### FIELD

Embodiments described herein relate generally to a photovoltaic cell module.

### BACKGROUND

An organic thin film photovoltaic cell is a photovoltaic cell prepared by using an organic thin film semiconductor in which a conductive polymer, fullerene and the like are combined. In the organic thin film photovoltaic cell, a photoelectric conversion film can be produced by a simple method such as coating or printing and a lower cost may be achieved, compared with a photovoltaic cell (hereinafter “photovoltaic cell” may be referred to as “PV” in the present specification) based on an inorganic material such as silicon, Cu—In—Ga—Se (CIGS) or CdTe. In contrast, there is such a problem that the photoelectric conversion efficiency and life of the organic thin film photovoltaic cell are low in comparison with inorganic photovoltaic cells in the related art.

Factors responsible for the decreased efficiency of an organic thin film photovoltaic cell module include such a factor that the moving distance of a carrier is short in the photoelectric conversion layer of a PV cell, it is necessary to therefore form the photoelectric conversion layer to be thin (around 100 nm), and, as a result, received light cannot be sufficiently absorbed and partially leaks out as reflected light. A further important factor responsible for the decreased efficiency is in that the voltage dependency of leakage current from the cell is high due to the physical properties of a material and it is thus necessary to limit a potential difference occurring in the electrode of the cell in a current direction by photocurrent to a low level. In other words, the width of the photoreceptor of the cell cannot be formed to be long, the area ratio of a gap region between cells to a cell region is relatively increased, an opening ratio cannot be therefore increased compared with PV modules based on other materials, and, as a result, module electricity generation efficiency extremely becomes low in comparison with small area cell efficiency.

Thus, various devices for improving the photoelectric conversion efficiency of a PV module have been accomplished. Examples thereof include the utilization of invalid light by a light guide (light management method) and a method of improving the packing density of modules by patterning using a laser or a trimming head. The light management has an advantage that decrease in electricity generation efficiency due to the cell size effect of a device is inhibited from occurring in comparison with the patterning method in which a cell width is limited by a gap width and an opening ratio.

In an organic thin film photovoltaic cell module 100 representative in the related art as illustrated in FIG. 1, PV cells 101 are disposed between a transparent substrate 102 and a sealing plate 103 and an optical member 106 is disposed to cover the PV cells 101. In the optical member 106, each gap space (slit) 105 of which the cross section has a triangular shape is formed at a position corresponding to each gap 104 between each PV cell 101 and another PV cell 101 adjacent to the PV cell 101. Light (A) that is approximately perpendicularly incident from the surface of the optical member 106 to each gap 104 is totally reflected on each slit surface and is guided to each PV cell 101. As a result, the effective opening ratio of the module can be improved nearly to 100% when the angle of incidence of the light (A) to the optical member 106 is approximately 90°.

However, when the angle of incidence to the optical member is low, the angle of incidence on the slit surface deviates from the total reflection condition and there is a condition that light is incident on each gap 104. Alternatively, in the case of light incident at a certain angle (e.g., light (A′)), reflected light thereof is guided to the surface of an adjacent slit, the light deviates from the condition of the angle of total reflection of light and is incident on each gap 104, and substantial decrease in opening ratio is inevitable.

As described above, there has been a problem that an opening ratio improvement effect in the light management is deteriorated depending on the angle of incidence of light. Accordingly, it has been difficult to avoid a phenomenon that the effect of the light management is deteriorated due to a seasonal factor of the orbit of the sun.

### BRIEF DESCRIPTION OF THE DRAWINGS

FIG. 1 is a cross-sectional view that illustrates an organic thin film photovoltaic cell module which is representative in the related art;

FIG. 2 is a cross-sectional view that illustrates an organic thin film photovoltaic cell;

FIG. 3 is a cross-sectional view that illustrates a photovoltaic cell module according to an embodiment;

FIG. 4 is a top view that illustrates the photoelectric conversion rate improvement structure of a photovoltaic cell module according to an embodiment;

FIG. 5 is a perspective view that illustrates a photovoltaic cell module according to an embodiment;

FIG. 6A is a view that illustrates a light management effect in a slit-shaped recess space in the case of observing a photovoltaic cell module from a top surface direction;

FIG. 6B is a view that illustrates a light management effect in a slit-shaped recess space in the case of observing a photovoltaic cell module from a cross sectional direction;

FIG. 7A is a view that illustrates a light management effect in a photovoltaic cell module according to an embodiment in the case of observing the photovoltaic cell module from a top surface direction;

FIG. 7B is a view that illustrates a light management effect in a photovoltaic cell module according to an embodiment in the case of observing the photovoltaic cell module from a cross sectional direction;

FIG. 8A is a cross-sectional view that illustrates a photovoltaic cell module according to an embodiment, the photovoltaic cell module having a slit-shaped recess space having an inner wall surface which is a curved surface;

FIG. 8B is a cross-sectional view that illustrates a photovoltaic cell module according to an embodiment, the photovoltaic cell module having a slit-shaped recess space having an inner wall surface which is a side surface of a trapezoidal transparent member;

FIG. 9 is a cross-sectional view that illustrates a photovoltaic cell module according to an embodiment;

FIG. 10 is a cross-sectional view that illustrates a photovoltaic cell module according to an embodiment;

FIG. 11 is a cross-sectional view that illustrates a photovoltaic cell module according to an embodiment;

FIG. 12 is a cross-sectional view that illustrates a photovoltaic cell module according to an embodiment; and

FIG. 13 is a perspective view that illustrates a moth-eye-type nanostructure applicable as a low-reflection film in a photovoltaic cell module according to an embodiment.

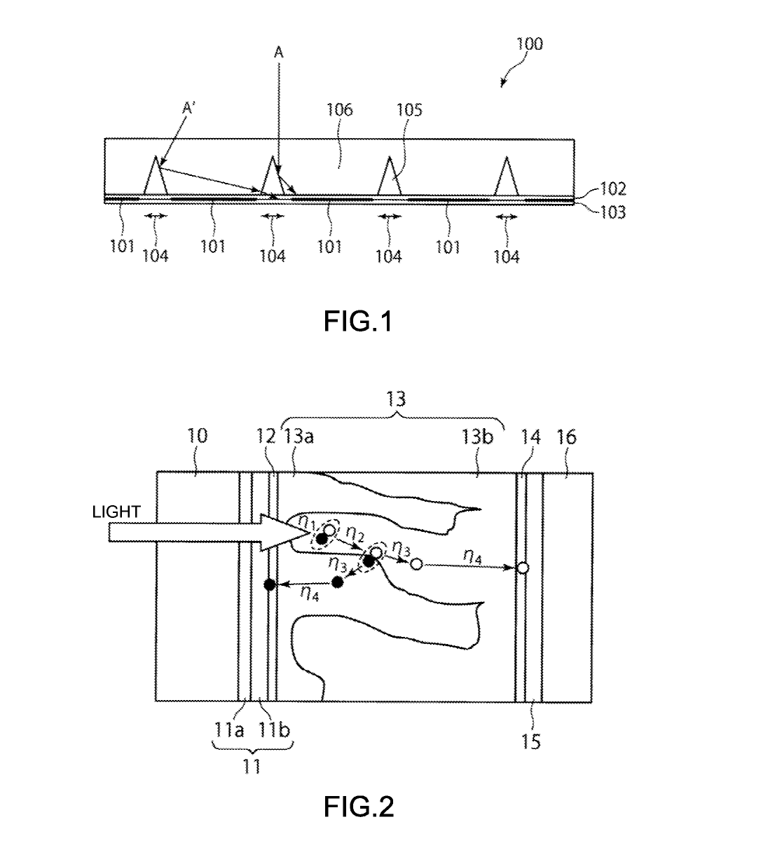

### DETAILED DESCRIPTION

A photovoltaic cell module according to an embodiment of the present invention includes a substrate; a plurality of photovoltaic cells disposed via an individual gap on the substrate; and a transparent member disposed to cover the photovoltaic cells, and is configured so that light incident on the transparent member passes through the transparent member and arrives at the photovoltaic cells, wherein the transparent member has a slit-shaped recess space at a position corresponding to the individual gap between the photovoltaic cells; and the photovoltaic cell module includes a photoelectric conversion rate improvement structure on a surface side of the transparent member, on which light is incident.

Embodiments will now be explained with reference to the accompanying drawings. In addition, preferred embodiments among the embodiments of the present invention are exemplified below and the scope of the present invention is not thus limited only to the scopes of the specific embodiments exemplified below.

FIG. 2 is a cross-sectional configuration view that illustrates one specific embodiment of the organic thin film photovoltaic cell. A hole transport layer 12, a photoelectric conversion layer 13, and an electron transport layer 14 are successively stacked on an anode 11 composed of a transparent electrode 11a and a metal auxiliary electrode 11b, formed on a substrate 10. The photoelectric conversion layer 13 is preferably a thin film having a structure with a bulk heterojunction of a p-type semiconductor 13a and an n-type semiconductor 13b. A cathode 15 is formed on the electron transport layer 14 and a sealing material 16 is further provided on the surface of the photovoltaic cell. Signs ∘ and denote an electron and a hole, respectively.

The photovoltaic cell has a basic structure including the anode 11, the photoelectric conversion layer 13 and the opposite electrode (cathode) 15 and such a photovoltaic cell can be obtained by, for example, vapor-depositing aluminum onto the sealing material 16 to form the cathode 15, providing the photoelectric conversion layer 13 thereon, and further forming the anode 11 with transparency by sputtering or coating. As illustrated in FIG. 2, it is desirable to provide, as intermediate layers, the hole transport layer 12 including a hole transport material such as PEDOT/PSS or molybdenum oxide and/or the electron transport layer 14 including an electron transport material such as TiOₓ or metal Ca, between the electrodes (the anode 11 and the cathode 15) and the photoelectric conversion layer 13.

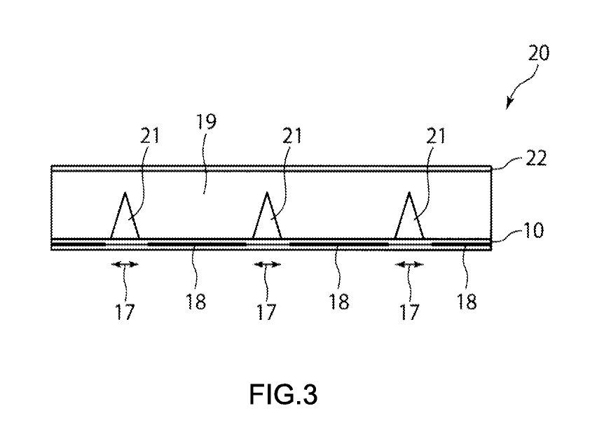

FIG. 3 is a cross-sectional view of a preferred example (basic configuration view) of a photovoltaic cell module according to an embodiment of the present invention.

In FIG. 3, there is illustrated the photovoltaic cell module 20 including a plurality of photovoltaic cells 18 disposed via each gap 17 on a substrate 10; and a transparent member 19 disposed to cover the photovoltaic cell 18, and is configured so that light incident on the transparent member 19 passes through the transparent member 19 and arrives at the photovoltaic cell 18, wherein the transparent member 19 includes a slit-shaped recess space 21 at a position corresponding to each gap 17 of the photovoltaic cell 18; and the photovoltaic cell module 20 includes a photoelectric conversion rate improvement structure 22 on a surface side of the transparent member 19, on which light is incident.

In FIG. 3, there are illustrated three slit-shaped recess spaces 21 at positions corresponding to the gaps 17 between the photovoltaic cells 18 in the transparent member 19. The number of the slit-shaped recess spaces 21 is arbitrary. Similarly, the number of the photovoltaic cells 18 and the number of the gaps 17 are also arbitrary.

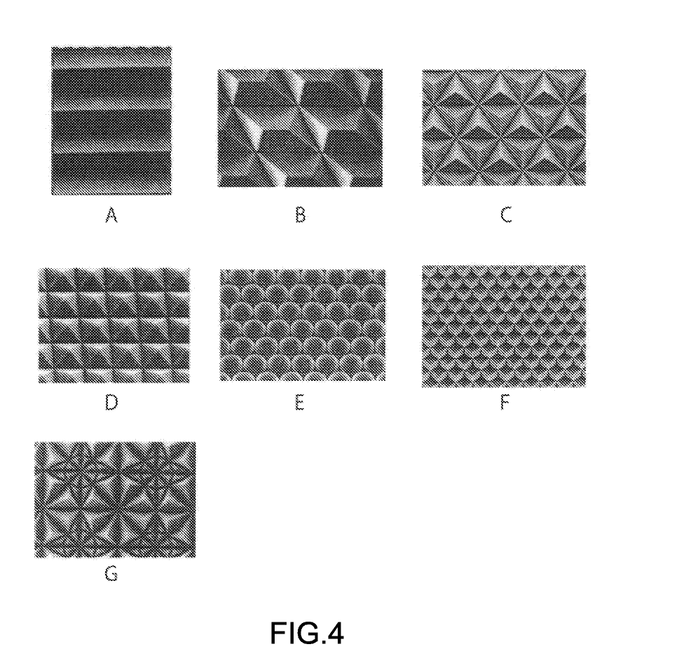

Examples of the photoelectric conversion rate improvement structure 22 include structures illustrated in FIG. 4 which is the top view of the photoelectric conversion rate improvement structure 22, e.g., preferably a line prism (FIG. 4A), a structure in which a line prism is partially divided (FIG. 4B), a combination of pyramids of which the shapes of the bottom surfaces are polygonal (such as a combination of pyramids of which the bottom surfaces are triangular (FIG. 4C) or a combination of pyramids of which the bottom surfaces are rectangular (FIG. 4D)), a combination of circular cones, a combination of hemispheres (FIG. 4E), a combination of minute line prisms (FIG. 4F), a combination of other minute photoelectric conversion rate improvement structures (FIG. 4G), and the like. Especially, the line prism (FIG. 4A) is particularly preferred.

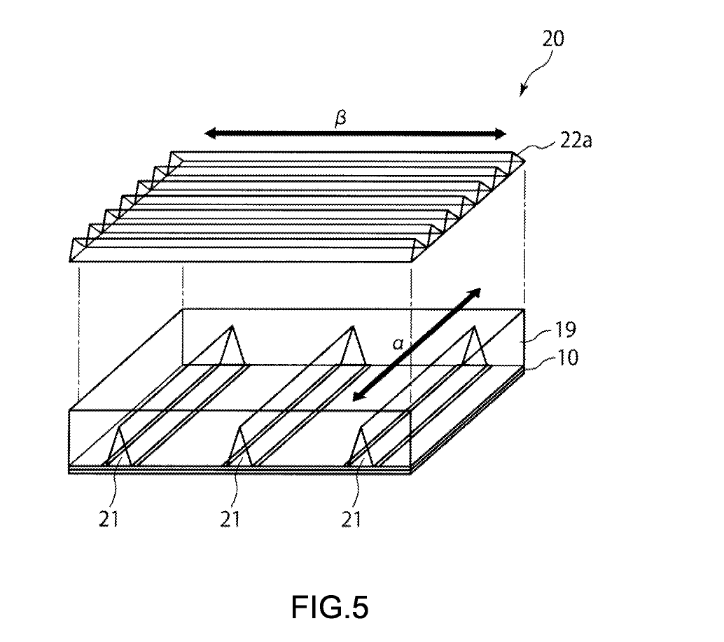

FIG. 5 is the perspective view of the photovoltaic cell module 20 according to the embodiment of the present invention, including line prisms 22a with the structure illustrated in FIG. 4A as the photoelectric conversion rate improvement structure 22. Although the line prisms 22a and the transparent member 19 which are divided are drawn in FIG. 5, the line prisms 22a and the transparent member 19 are integrated or contiguous, as is apparent from the cross-sectional view of FIG. 3. In FIG. 5, α is a directional line indicating the direction of a continuous line prepared by connecting the vertexes of each slit-shaped recess space 21 while β is a directional line indicating the direction of a continuous line prepared by connecting the vertexes of each line prism 22a.

In FIG. 5, there is particularly illustrated the case in which the crossing angle between the direction of each slit-shaped recess space 21 (direction of directional line α) and the direction of each line prism 22a (direction of directional line β) is 90°.

In the photovoltaic cell module according to an embodiment of the present invention, the crossing angle between the direction of each slit-shaped recess space 21 (direction of directional line α) and the direction of each line 22a (direction of directional line β) is 30 to 90°, preferably 45 to 90°, particularly preferably 80 to 90°. The case of the crossing angle of less than 30° is not preferred since the rate of light incident on the gaps between the cells is increased.

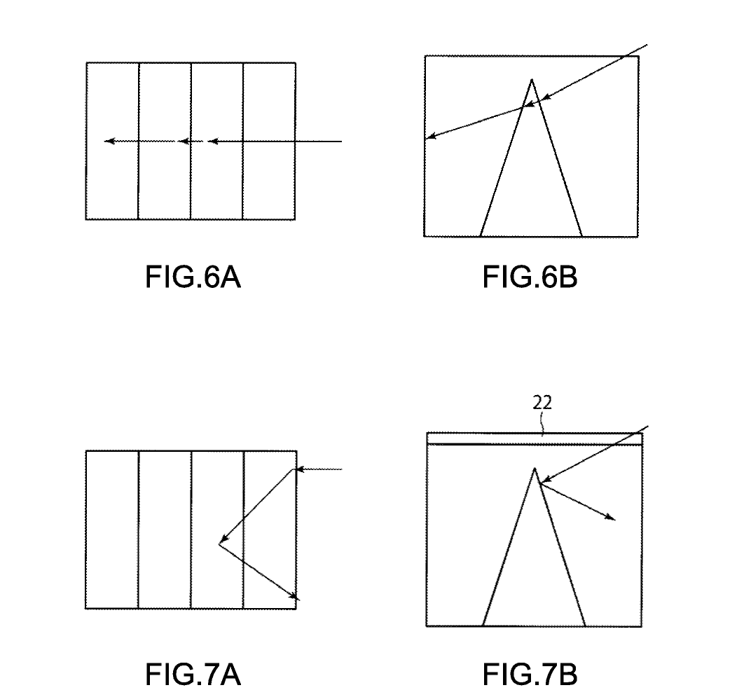

FIG. 6 and FIG. 7 are views that give explanations about the effect of light management achieved by a photovoltaic cell module according to an embodiment of the present invention. FIG. 6 illustrates the state of refraction of light in a photovoltaic cell module in the related art, which has a slit-shaped recess space but does not have any photoelectric conversion rate improvement structure on the surface thereof while FIG. 7 illustrates the state of refraction of light in a photovoltaic cell module according to an embodiment of the present invention, which has a slit-shaped recess space and a photoelectric conversion rate improvement structure 22. FIG. 6A and FIG. 7A are in the case of observing each photovoltaic cell module from a top surface direction while FIG. 6B and FIG. 7B are in the case of observing each photovoltaic cell module from a cross sectional direction.

As illustrated in FIG. 6A and FIG. 6B, in the photovoltaic cell module in the related art, light incident on a transparent member at a very low angle is incident on a slit plane (e.g., about 70 degree inclined plane) at a higher angle than the angle of total reflection. Under this condition, most of light passes through the slit plane and is incident into the slit space. A part of the light is incident on a gap between photovoltaic cells and does not contribute to generation of electricity. In contrast, as illustrated in FIG. 7A and FIG. 7B, in the organic thin film photovoltaic cell module according to the embodiment of the present invention, incident light is refracted at a certain angle with respect to the direction of formation of the slit by the photoelectric conversion rate improvement structure 22 formed on the surface of the transparent member. The refracted incident light is incident on the slit plane at an incidence angle vertical to the direction of the formation of the slit as well as at an angle in a parallel direction. As a result, the angle of incidence of light on the slit plane becomes lower than the angle of total reflection and light is totally reflected on the slit plane and is returned to a region in which photovoltaic cells are formed. This effect causes the effective opening ratio of the photovoltaic cell module to approach 100%.

As described above, the photoelectric conversion rate improvement structure encompasses the line prisms illustrated in FIG. 4 and other prisms. Although such a prism per se and the optical properties per se are known, it was quite unexpected by those skilled in the art that, when such a prism is applied to a photovoltaic cell module (particularly, an organic thin film photovoltaic cell module prepared by disposing a plurality of photovoltaic cells via gaps to be adjacent to each other and by using a transparent member in which slit-shaped recess spaces are formed at positions corresponding to the gaps), such a prism can function as a structure that improves the photoelectric conversion rate of the photovoltaic cell module.

<Photovoltaic Cell Module (Specific Configuration)>

A photovoltaic cell module according to a particularly preferred embodiment of the present invention is a bulk heterojunction type photovoltaic cell module. A bulk heterojunction type photoelectric conversion layer is characterized in that p-type and n-type semiconductors are blended and a nano-order pn junction spreads over the whole photoelectric conversion layer. Therefore, a pn junction region is wider than that in a stacked organic thin film photovoltaic cell in the related art and a region that actually contributes to generation of electricity also spreads over the whole photoelectric conversion layer. Accordingly, the region that contributes to the generation of electricity in the bulk heterojunction type organic thin film photovoltaic cell becomes overwhelmingly thick in comparison with the stacked organic thin film photovoltaic cell, the efficiency of absorption of photons is thus also improved, and current which can be extracted is also increased.

Each component of the organic thin film photovoltaic cell module according to an embodiment of the present invention will be described below.

<<Substrate>>

In the organic thin film photovoltaic cell module according to an embodiment of the present invention, the substrate 10 is intended mainly to support the other components. The substrate 10 preferably has sufficient durability under an environment or conditions during producing the photovoltaic cell module and during using the photovoltaic cell module and preferably, for example, is not easily changed in quality by heat or an organic solvent during forming an electrode. Examples of materials for the substrate 10 include inorganic materials such as alkali-free glass, quartz and glass; plastics such as polyethylene, polyethylene terephthalate (PET), polyethylene naphthalate (PEN), polyimide, polyamide, polyamide-imide, liquid crystal polymer and cycloolefin polymer; metal substrates such as polymeric films, stainless steel (SUS) and silicon; and the like. Especially, alkali-free glass and polyethylene naphthalate are particularly preferred.

The substrate 10 may be disposed on the light receiving surface side or non-light receiving surface side of a photovoltaic cell. When the substrate 10 is disposed on the light receiving surface side of the photovoltaic cell to generate electricity by light passing through the substrate 10, the substrate that is transparent is used. When the substrate 10 is disposed on the non-light receiving surface side of the photovoltaic cell, the substrate may be transparent or opaque. The thickness of the substrate 10 is not particularly limited as long as the substrate has strength sufficient for supporting the other components, but is preferably 0.5 to 2.0 mm.

<<Transparent Member>>

In the photovoltaic cell module according to an embodiment of the present invention, the transparent member 19 having a refractive index of 1.3 or more and 1.7 or less, particularly preferably 1.4 or more and 1.6 or less, may be used. The transparent member has a high light transmittance in a visible light region and weather resistance and a polymeric resin material such as acrylic resin, polycarbonate resin or a silicone resin is a material suitable for the transparent member. Alkali-free optical glass is suitable for the inorganic material.

Casting molding is possible in consideration of processability and acrylic resin of which the material cost is low is particularly preferred as a primary member.

Slit-Shaped Recess Space and Photoelectric Conversion Rate Improvement Structure

The transparent member 19 has the slit-shaped recess spaces 21 at the positions corresponding to the gaps 17 between the photovoltaic cells 18 and is provided with the photoelectric conversion rate improvement structure 22 on the surface side, on which light is incident, of the transparent member 19.

The slit-shaped recess space 21 preferably has a triangular cross-sectional shape and particularly preferably has an isosceles triangular cross-sectional shape. When the cross-sectional shape is isosceles triangular, the base angle thereof is 40 to 80°, preferably 50 to 75°, particularly preferably 60 to 70°. The length of the base of the isosceles triangle mainly depends on the length of each gap 17 between the photovoltaic cells 18 and may be set to be the same as the length of the gap 17 or a length in the range of −20% to +20% of the length of the gap 17. Accordingly, the length of the base is 0.8 to 4.0 mm, preferably 0.9 to 3.0 mm, particularly preferably 1.0 to 2.0 mm, while the height is 0.6 to 12 mm, preferably 0.8 to 6.0 mm, particularly preferably 0.9 to 3.0 mm.

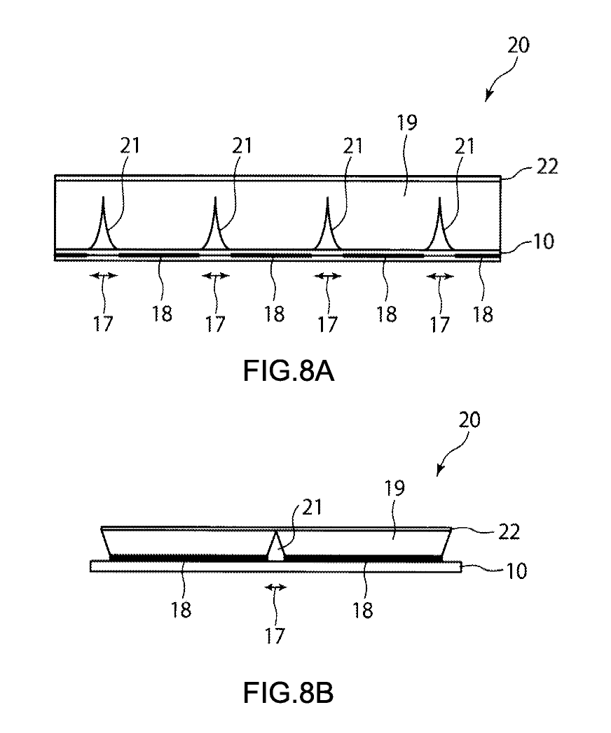

The slit-shaped recess space 21 also preferably has a slit inner wall surface that is a curved surface as illustrated in FIG. 8A.

The inside of each recess space 21 is typically and preferably filled with air or may also be filled with a material with a refractive index different from that of the transparent member 21 or a reflective material.

A method for forming each slit-shaped recess space 21 in the transparent member 19 is arbitrary. Examples of the method include: (A) a method of preparing a plate-like transparent member and then forming each slit-shaped recess space 21 in the transparent member by cutting and processing or other processes; (B) a method of supplying a transparent member in a molten or softened state into a die for forming each slit-shaped recess space 21 and then curing the member; (C) a method of preparing a plurality of transparent members of which the cross-sectional shapes are trapezoidal and placing the members so that the side surfaces of the plurality of trapezoidal transparent members are the inner wall surfaces of slit-shaped recess spaces 21 (FIG. 8B); and the like. Among them, the method (B) is most preferred from the viewpoint of the surface roughness of each slit-shaped recess space and a production cost.

A method for placing the photoelectric conversion rate improvement structure on the surface of the transparent member is also arbitrary. Examples of the method include: (D) a method of preparing a plate-like transparent member and then forming a photoelectric conversion rate improvement structure on the surface of the transparent member by cutting and processing or other processes; (E) a method of supplying a transparent member in a molten or softened state into a die for forming a certain photoelectric conversion rate improvement structure and then curing the member; (F) a method of separately preparing “plate-like transparent member” and “transparent member having photoelectric conversion rate improvement structure on surface” and then joining both of the transparent members; and the like. “Plate-like transparent member” in (F) encompasses both of a member that has the slit-shaped recess spaces 19 and a member that does not have any slit-shaped recess space 19. In the case of the latter member that does not have any slit-shaped recess space 19, slit-shaped recess spaces 19 can be formed after joining “transparent member having photoelectric conversion rate improvement structure on surface”. “Plate-like transparent member” and “transparent member having photoelectric conversion rate improvement structure on surface” in (F) may comprise the same material or different materials. Acrylic resin may be used as “plate-like transparent member”, of which the abundance ratio is relatively high, with attachment of great importance to optical properties, while polycarbonate resin may be used as “transparent member having photoelectric conversion rate improvement structure on surface” exposed to an external environment in consideration of physical or mechanical properties. Such a configuration is particularly suitable for addressing an environment in which physical wearing due to dust or the like often occurs.

When “plate-like transparent member” and “transparent member having photoelectric conversion rate improvement structure on surface” are joined in (F), adhesive-cum-refractive index adjustment materials such as various transparent potting agents, various silicone gels, various silicone sols, and various glass/acryl adhesives (for example, preferably, PHOTOBOND manufactured by Sunrise MSI Corporation, etc.) are applicable, particularly in the case in which the optical properties, e.g. refractive indices, of both members are different.

<<Photovoltaic Cell>>

Each component other than the photovoltaic cell according to an embodiment of the present invention will be described below.

Anode

As illustrated in FIG. 2, the anode 11 is formed on the substrate 10. A material for the anode 11 is not particularly limited as long as the material has electrical conductivity. Typically, the anode 11 can be formed by forming a film with a transparent or semi-transparent material having electrical conductivity by a vacuum deposition method, a sputtering method, an ion plating method, a plating method, a coating method, or the like.

Examples of the transparent or semi-transparent electrode material include electrically-conductive metal oxide films, semi-transparent metallic thin films, and the like. Specifically, a film produced using electrically conductive glass comprising indium oxide, zinc oxide, tin oxide; indium tin oxide (ITO), fluorine-doped tin oxide (FTO) or indium zinc oxide, which is a composite thereof; or the like (NESA or the like), gold, platinum, silver, copper, or the like is used. Particularly, ITO or FTO is preferred. Polyaniline and derivatives thereof, polythiophene and derivatives thereof, and the like, which are organic conductive polymers, may also be used as such electrode materials.

The film thickness of the anode 11 is preferably 30 to 300 nm in the case of ITO. The thickness of less than 30 nm results in reduction in electrical conductivity to increase resistance and thus causes photoelectric conversion efficiency to be decreased. When the thickness is more than 300 nm, ITO has no flexibility and may be cracked by applying stress.

The sheet resistance of the anode 11 is preferably as low as possible and is preferably 10Ω/square or less. The anode 11 may be a single layer or may be prepared by stacking layers comprising materials having different work functions.

Hole Transport Layer

The hole transport layer 12 is optionally disposed between the anode 11 and the photoelectric conversion layer 13. The functions of the hole transport layer 12 are: to level the recesses and projections of an electrode in a lower layer to prevent a photovoltaic cell element from short-circuiting; to efficiently transport only holes; to prevent excitons generated in the vicinity of the interface between the hole transport layer 12 and the photoelectric conversion layer 13 from disappearing; and the like. A material for the hole transport layer 12 is preferably a polythiophene-based polymer such as PEDOT/PSS (poly(3,4-ethylenedioxythiophene)-poly(styrenesulfonate)) or an organic conductive polymer such as polyaniline or polypyrrole. Examples of representative products of the polythiophene-based polymer include Clevios PH500, Clevios PH, Clevios PV P AI 4083, and Clevios HIL1.1 from H.C. Starck GmbH. As an inorganic material, molybdenum oxide is a preferable material.

When Clevios PH500 is used as the material for the hole transport layer 12, a film thickness is preferably 20 to 100 nm. When the thickness is too small, the effect of preventing a lower electrode from short-circuiting is lost to make a short circuit. When the thickness is too large, film resistance is increased to restrict generated electric current and phototranstormation efficiency is therefore decreased.

A method for forming the hole transport layer 12 is not particularly limited as long as the method is a method capable of forming a thin film. For example, the layer can be coated by a spin coating method. A material for the hole transport layer 12 can be coated in a desired film thickness, followed by heat-drying the material by a hot plate or the like. It is preferable to heat-dry the material at 140 to 200° C. for around several minutes to 10 minutes. It is desirable to use a solution to be coated, which has been filtrated through a filter beforehand.

Photoelectric Conversion Layer

The photoelectric conversion layer 13 is disposed between the anode 11 and the cathode 15. The photovoltaic cell according to a preferred embodiment of the present invention is a bulk heterojunction type photovoltaic cell.

The bulk heterojunction type photovoltaic cell is characterized in that p-type and n-type semiconductors are mixed in a photoelectric conversion layer to form a microlayer separation structure. In the bulk heterojunction type, the p-type and n-type semiconductors which are mixed form a pn junction with a nano-order size in the photoelectric conversion layer and electric current is obtained using photocharge separation occurring on a junction surface. The p-type semiconductor is composed of a material having an electron-donating property. In contrast, the n-type semiconductor is composed of a material having an electron-accepting property. In accordance with an embodiment of the present invention, at least one of the p-type semiconductor and the n-type semiconductor may be an organic semiconductor.

For a p-type organic semiconductor, it is preferable to use, for example, polythiophene and derivatives thereof, polypyrrole and derivatives thereof, pyrazoline derivatives, arylamine derivatives, stilbene derivatives, triphenyldiamine derivatives, oligothiophene and derivatives thereof, polyvinylcarbazole and derivatives thereof, polysilane and derivatives thereof, polysiloxane derivatives having aromatic amine in a side or main chain, polyaniline and derivatives thereof, phthalocyanine derivatives, porphyrin and derivatives thereof, polyphenylenevinylene and derivatives thereof, polythienylenevinylene and derivatives thereof, and the like. They may also be used in combination. There may also be used copolymers thereof, examples of which include a thiophene-fluorene copolymer, a phenyleneethynylene-phenylenevinylene copolymer, and the like.

The preferred p-type organic semiconductor comprises polythiophene or a derivative thereof which is a n-conjugated conductive polymer. Polythiophene and derivatives thereof are characterized in that excellent stereoregularity can be secured and solubility into a solvent is comparatively high. Polythiophene and derivatives thereof are not particularly limited as long as they are compounds having a thiophene skeleton.

Specific examples of such polythiophene and derivatives thereof include polyalkylthiophenes such as poly(3-methylthiophene), poly(3-butylthiophene), poly(3-hexylthiophene), poly(3-octylthiophene), poly(3-decylthiophene) and poly(3-dodecylthiophene); polyarylthiophenes such as poly(3-phenylthiophene) and poly(3-p-alkylphenylthiophene); polyalkylisothionaphthenes such as poly(3-butylisothionaphthene), poly(3-hexylisothionaphthene), poly(3-octylisothionaphthene) and poly(3-decylisothionaphthene); polyethylenedioxythiophene; and the like.

In recent years, a derivative such as PCDTBT (poly[N-9″-hepta-decanyl-2,7-carbazole-alt-5,5-(4′,7′-di-2-thienyl-2′,1′,3′-benzothiadiazole)]) as a copolymer comprising carbazole, benzothiadiazole and thiophene has been known as a compound by which excellent photoelectric conversion efficiency is obtained. Each compound described above is applicable in accordance with an embodiment of the present invention.

A film can be formed with the conductive polymers by coating a solution dissolved in a solvent. Accordingly, there is an advantage that an organic thin film photovoltaic cell with a large area can be manufactured at a low cost in an inexpensive facility by a printing method or the like.

For the n-type organic semiconductor, fullerene and derivatives thereof are preferably used. A fullerene derivative as used herein is not particularly limited as long as the derivative has a fullerene skeleton. Specific examples thereof include derivatives formed by using C60, C70, C76, C78, C84, and the like as basic skeletons. In the fullerene derivative, carbon atoms in the fullerene skeleton may be modified by arbitrary functional groups and the functional groups may be bound to each other to form a ring. Examples of the fullerene derivative include a fullerene-binding polymer. A fullerene derivative that contains a functional group having a high affinity for a solvent and is highly soluble in a solvent is preferable.

Examples of the functional group in the fullerene derivative include a hydrogen atom; a hydroxyl group; halogen atoms such as a fluorine atom and a chlorine atom; alkyl groups such as a methyl group and an ethyl group; alkenyl groups such as a vinyl group; a cyano group; alkoxy groups such as a methoxy group and an ethoxy group; aromatic hydrocarbon groups such as a phenyl group and a naphthyl group; aromatic heterocyclic groups such as a thienyl group and a pyridyl group; and the like. Specific examples thereof include hydrogenated fullerenes such as C60H36 and C70H36; oxide fullerenes such as C60 and C70; fullerene metal complexes; and the like.

Among the above, it is particularly preferable to use 60PCBM ([6,6]-phenyl C61 methyl butyrate ester) or 70PCBM ([6,6]-phenyl C71 methyl butyrate ester) as the fullerene derivative.

It is preferable to use C70 when unmodified fullerene is used. Fullerene C70 has a high photo-carrier generation efficiency and is suitable for use in the organic thin film photovoltaic cell.

The mixing ratio of the n-type organic semiconductor and the p-type organic semiconductor in the photoelectric conversion layer is preferably about n:p=1:1 as the content of the n-type organic semiconductor when the p-type semiconductor is a P3AT-based semiconductor. When the p-type semiconductor is a PCDTBT-based semiconductor, the mixing ratio of the n-type organic semiconductor and the p-type organic semiconductor is preferably about n:p=4:1.

In order to coat an organic semiconductor, dissolution in a solvent is generally performed. Examples of the solvent used therefor include unsaturated hydrocarbon-based solvents such as toluene, xylene, tetralin, decalin, mesitylene, n-butylbenzene, sec-butylbenzene and tert-butylbenzene; halogenated aromatic hydrocarbon-based solvents such as chlorobenzene, dichlorobenzene and trichlorobenzene; halogenated saturated hydrocarbon-based solvents such as carbon tetrachloride, chloroform, dichloromethane, dichloroethane, chlorobutane, bromobutane, chloropentane, chlorohexane, bromohexane and chlorocyclohexane; and ethers such as tetrahydrofuran and tetrahydropyran. Halogen-based aromatic solvents are particularly preferred. The solvents may be used singly or in the form of a mixture.

Examples of methods for coating a solution to form a film include spin coating, dip coating, casting, bar coating, roll coating, wire bar coating, spraying, screen printing, gravure printing, flexographic printing, offset printing, gravure offset printing, dispenser coating, nozzle coating, capillary coating, and inkjet methods, etc. The coating methods may be used singly or in combination.

Electron Transport Layer

The electron transport layer 14 is optionally disposed between the cathode 15 and the photoelectric conversion layer 13. The electron transport layer 14 has a function of blocking holes to efficiently transport only electrons and a function of preventing excitons generated at the interface between the photoelectric conversion layer 13 and the electron transport layer 14 from disappearing.

Examples of materials for the electron transport layer 14 include metal oxides such as amorphous titanium oxide obtained by hydrolyzing titanium alkoxide by the sol-gel method.

The film formation method is not particularly limited as long as a thin film can be formed. Examples of the film formation method include a spin coating method. It is desirable to form a film with a film thickness of 5 to 20 nm when titanium oxide is used as the material for the electron transport layer. When the film thickness is smaller than the above-described range, the hole blocking effect is deteriorated. Therefore, generated excitons are deactivated before dissociating into electrons and holes, and electric current cannot be efficiently extracted. When the film thickness is too large, the film resistance is increased, generated electric current is limited, and phototranstormation efficiency is therefore decreased. It is desirable to use a coating solution that has been filtrated through a filter beforehand. After coating a film with a predetermined thickness, the film can be heat-dried using a hot plate or the like. The film is heat-dried at 50° C. to 100° C. for around several minutes to 10 minutes while promoting hydrolysis in the air. Metal calcium is a preferable material as the inorganic material.

Cathode

The cathode 15 is stacked on the photoelectric conversion layer 13 (or the electron transport layer 14). It is preferable to form a film with a material having electrical conductivity by a vacuum deposition method, a sputtering method, an ion plating method, a plating method, a coating method, or the like. Examples of the electrode material include electrically-conductive metallic thin films, metal oxide films, and the like. It is preferable to use a material having a low work function in the cathode 15 when the anode 11 is formed using a material having a high work function. Examples of the material having a low work function include alkali metals, alkaline earth metals, and the like. Particularly preferred specific examples include Li, In, Al, Ca, Mg, Sm, Tb, Yb, Zr, Na, K, Rb, Cs, Ba, and alloys thereof.

The cathode 15 may be a single layer or may be prepared by stacking layers comprising materials having different work functions. The material may also be an alloy of one or more of the materials having low work functions, and gold, silver, platinum, copper, manganese, titanium, cobalt, nickel, tungsten, tin, etc. Examples of particularly preferred alloys include a lithium-aluminum alloy, a lithium-magnesium alloy, a lithium-indium alloy, a magnesium-silver alloy, a magnesium-indium alloy, a magnesium-aluminum alloy, an indium-silver alloy, a calcium-aluminum alloy, and the like.

The film thickness of the cathode 15 is 1 nm to 500 nm, preferably 10 nm to 300 nm. When the film thickness is smaller than the above-described range, resistance becomes too high and generated charge cannot be sufficiently transferred to an external circuit. When the film thickness is larger than the above-described range, the formation of the cathode 15 requires long time and, therefore, material temperature may be excessively increased to damage an organic layer to deteriorate performance. Further, a large amount of material is used. Therefore, the occupation time of the film formation apparatus is prolonged to lead to increase in cost.

<Other Preferred Embodiments of the Present Invention, Etc.>

As described above, FIG. 3 is a cross-sectional view of a preferred example (basic configuration view) of the photovoltaic cell module according to an embodiment of the present invention. FIG. 5 illustrates the photovoltaic cell module 20 according to an embodiment of the present invention, in which the line prisms are adopted as the photoelectric conversion rate improvement structure 22. In the photoelectric conversion rate improvement structure, a sheet having the photoelectric conversion rate improvement structure may be adhered to the transparent member with a flat surface or both may be integrated and molded by, e.g., a casting method.

An advantage of the configuration in which the sheet is adhered is in that inhibition to deterioration due to blasting of dust or the like can be caused, for example, by using polycarbonate, which is mechanically tough, in the photoelectric conversion rate improvement structure and by using acryl resin, which is excellent in light resistance and optical transparency, in the transparent member, since the materials of the transparent member and the photoelectric conversion rate improvement structure can be changed. Further, examples of such advantages include an advantage in that only adhering and replacement of a sheet are needed for repair for deterioration and the cost is low. In contrast, examples of advantages of the integration molding include an advantage in that a cost for manufacturing an organic thin film photovoltaic cell module becomes lower.

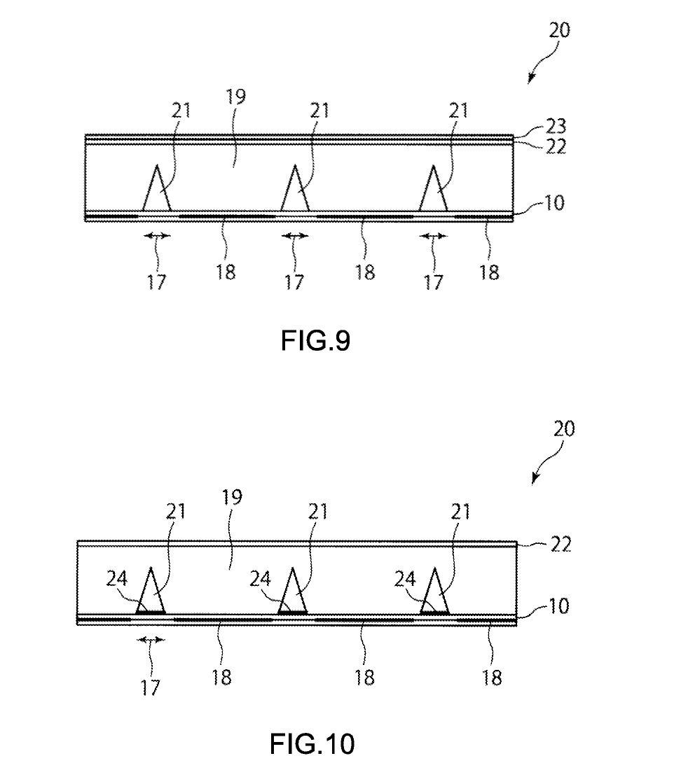

FIG. 9 is a cross-sectional view that illustrates the configuration of an improved example of the photovoltaic cell module according to an embodiment of the present invention. There is a characteristic in that, in addition to the basic structure of FIG. 3, a low-reflection film 23 is disposed on the surface of the photoelectric conversion rate improvement structure 22. The low-reflection film preferably has a reflectance of 2% or less, particularly preferably 0.1% or less. Any material can be adopted as a material for forming the low-reflection film. Examples of such particularly preferred materials include MgF₂. The low-reflection film 23 is not limited to a MgF₂ single layer but also encompasses multilayer films containing MgF₂.

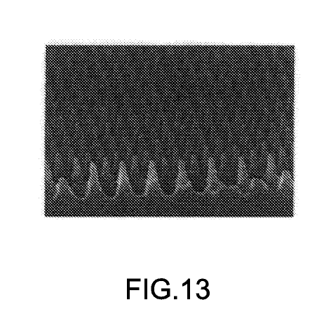

As the low-reflection film 23, a low-reflection film, in which a moth-eye type nanostructure (FIG. 13) is formed with a material similar to that of the transparent member 19 or photoelectric conversion rate improvement structure 22 described above, or a low-reflection film, in which a moth-eye type nanostructure is further formed on the above-described MgF₂ layer or the like, may be used.

FIG. 10 is a cross-sectional view that illustrates the configuration of another improved example of the photovoltaic cell module according to an embodiment of the present invention. There is a characteristic in that, in addition to the basic structure of FIG. 3, materials 24 with light reflectivity and (or) a light diffusion property are placed on the substrate facing surfaces of the gaps between the photovoltaic cells. The materials 24 with light reflectivity and (or) a light diffusion property enable a part of light leaked into the slit-shaped recess spaces 21 to be subjected to multiple-reflection or diffusion, to be incident on the photovoltaic cells, and to be reused. A material with light reflectivity and a material with a light diffusion property may be stacked at the positions facing the gaps 17 in the plane, in which the photovoltaic cells are not formed, of the transparent substrate 10, to form a light diffusion reflecting surface having a two-layer structure.

As the materials 24 with light reflectivity and (or) a light diffusion property, for example, materials having surfaces with high reflectances, e.g., metals, such as aluminum and chromium, of which the surface is thoroughly polished; mirror-like reflecting plates in which reflection films are disposed on the surfaces, of glass, resin and the like by silver plating; reflecting plates in which metals (particularly preferably aluminum) are vapor-deposited on the surfaces of glass, resin and the like; various metal foils; and the like can be used. Specifically, a reflecting plate having a reflectance of 97% or more can be produced by selecting, e.g., a reflective film “Vikuiti ESR” manufactured by Sumitomo 3M Limited, “LOUIREMIRROR” from Reiko Co., Ltd., or the like. As a light scattering material with a high reflectance, a microcellular foamed film (with a diffuse reflectance of 98% or more), of which a representative example is “MCPET” manufactured by Furukawa Electric Co., Ltd., may also be applied.

When a reflection layer is formed with one film, the configuration in which a stripe film prepared by alternately forming, on a film, anti-reflection films having a structure of which a representative example is a moth-eye structure and light scattering complete reflection layers having a structure of which a representative example is a microcellular foam structure is fitted to the positions of the photovoltaic cells 18 and the gaps 17 (the anti-reflection films are placed at the cell positions and the complete reflection films are placed at the gap positions) and is adhered to the back surface of the substrate is also effective. There is also a structure in which a light diffusion sheet is stacked on a reflecting mirror surface, as a further different reflection layer configuration. Examples of the stacked structure are a configuration in which the sheet is directly stacked on the mirror surface and a configuration in which the mirror surface and the light diffusion sheet are formed via a transparent substrate to face each other.

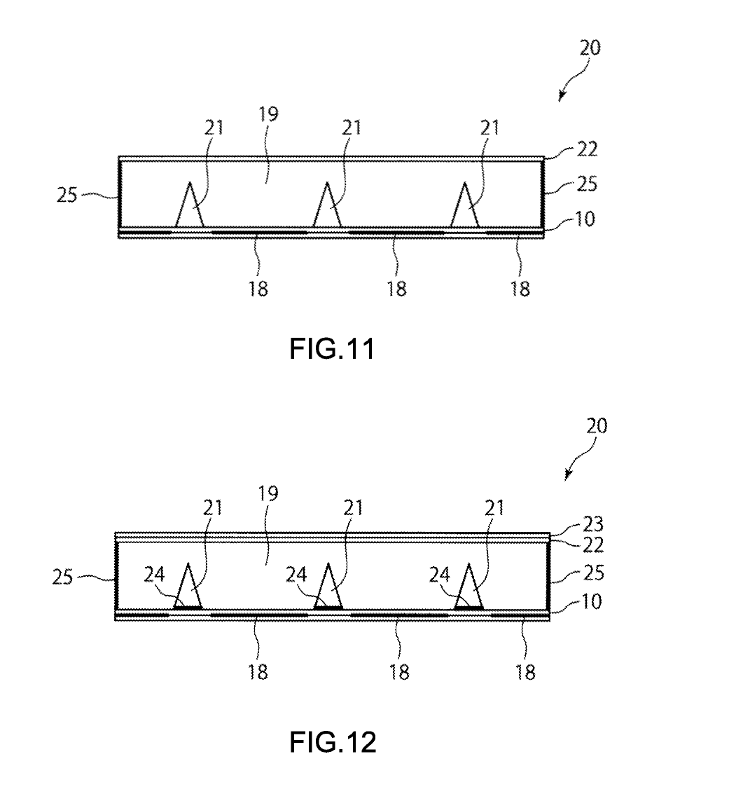

FIG. 11 is a cross-sectional view that illustrates the configuration of an improved example of the photovoltaic cell module according to an embodiment of the present invention. There is a characteristic in that, in addition to the basic structure of FIG. 3, reflectors 25 are placed on the sides of the optical member 19. The reflectors 25 have the effect of shutting light in the optical member 19 and contribute to the improvement of electricity generation efficiency. Preferred examples of the reflection layers 25 include layers prepared by forming metals with high reflectances, such as silver and aluminum, as thin film mirror surfaces, on the sides of the transparent member 19 by a method such as vapor deposition, sputtering, or ion plating. The configuration in which a part of the reflectors is coated with an insulator film also exists as a variation of the present invention.

FIG. 12 is a cross-sectional view that illustrates the configuration of an example the improvements of FIGS. 9, 10, and 11 are applied to the photovoltaic cell module according to an embodiment of the present invention. There is a characteristic in that, in addition to the basic structure of FIG. 3, the low-reflection film 23, the materials 24 with light reflectivity and (or) a light diffusion property, and the reflectors 25 are placed.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fail within the scope and spirit of the inventions.

1. A photovoltaic cell module comprising a substrate; a plurality of photovoltaic cells disposed via an individual gap on the substrate; and a transparent member disposed to cover the photovoltaic cells, and configured so that light incident on the transparent member passes through the transparent member and arrives at the photovoltaic cells, wherein
the transparent member has a slit-shaped recess space at a position corresponding to the individual gap between the photovoltaic cells; and
the photovoltaic cell module comprises a photoelectric conversion rate improvement structure on a surface side of the transparent member, on which light is incident.

2. The photovoltaic cell module according to claim 1, wherein the transparent member has a refractive index of L3 or more and 1.7 or less.

3. The photovoltaic cell module according to claim 1, wherein the slit-shaped recess space has a triangular cross-sectional shape.

4. The photovoltaic cell module according to claim 1, wherein
the photoelectric conversion rate improvement structure is each line prism which has a triangular cross-sectional shape; and
the line prism is disposed so that the direction of a continuous line prepared by connecting the vertexes of each line prism and the direction of a continuous line prepared by connecting the vertexes of the slit-shaped recess space cross.

5. The photovoltaic cell module according to claim 1, wherein
the plurality of photovoltaic cells comprise a photoelectric conversion layer; a transparent electrode disposed on one surface of the photoelectric conversion layer; and an opposite electrode disposed on a surface opposite to the surface, on which the transference electrode is disposed, of the photoelectric conversion layer.

6. The photovoltaic cell module according to claim 1, wherein a low-reflection film is formed on a surface of the photoelectric conversion rate improvement structure.

7. The photovoltaic cell module according to claim 1, wherein a light reflection material is disposed at a position corresponding to the individual gap between the photovoltaic cells, of the substrate.
